(19) United States
(12) Patent Application Publication
(10) Pub. No.: US 2025/0194036 A1
(43) Pub. Date: Jun. 12, 2025

(54) ELECTRICAL ASSEMBLY

(71) Applicant: Lear Corporation, Southfield, MI (US)

(72) Inventors: Raúl Ricart, Valls (ES); Antoni Ferré Fàbregas, Valls (ES)

(73) Assignee: Lear Corporation, Southfield, MI (US)

(21) Appl. No.: 18/940,319

(22) Filed: Nov. 7, 2024

Related U.S. Application Data
(60) Provisional application No. 63/606,659, filed on Dec. 6, 2023.

(51) Int. Cl. H05K 7/04; B60R 16/023; H05K 7/18

(52) U.S. Cl. CPC H05K 7/04; H05K 7/183; B60R 16/023

(57) ABSTRACT

An electrical assembly comprising an electronic control unit (ECU); a track assembly electrically connected to the ECU, the track assembly including a first conductor and a second conductor; and a support assembly configured for connection with and movement along the track assembly relative to the ECU, the support assembly including: a first sensor, a second sensor, and a sensor enabler electrically connected to the first sensor and the second sensor, the sensor enabler including a first terminal, a second terminal, and at least one of a diode, a comparator, or a switch. The sensor enabler may selectively electrically connect the first sensor or the second sensor with the first terminal and the second terminal according to an output from the ECU.

### CROSS-REFERENCE TO RELATED APPLICATIONS

This application claims the benefit of and priority to U.S. Provisional Application 63/606,659 filed Dec. 6, 2023, the disclosure of which is hereby incorporated by reference in its entirety as though fully set forth herein.

### TECHNICAL FIELD

The present disclosure generally relates to electrical assemblies, including electrical assemblies that include track assemblies and/or that may, for example, be used in connection with vehicles.

### BRIEF DESCRIPTION OF THE DRAWINGS

While the claims are not limited to a specific illustration, an appreciation of various aspects may be gained through a discussion of various examples. The drawings are not necessarily to scale, and certain features may be exaggerated or hidden to better illustrate and explain an innovative aspect of an example. Further, the exemplary illustrations described herein are not exhaustive or otherwise limiting, and embodiments are not restricted to the precise form and configuration shown in the drawings or disclosed in the following detailed description. Exemplary illustrations are described in detail by referring to the drawings as follows:

FIG. 1 is a schematic view generally illustrating an embodiment of an electrical assembly according to teachings of the present disclosure.

FIG. 2 is an end view generally illustrating an embodiment of an electrical assembly according to teachings of the present disclosure.

FIG. 3 is an end view generally illustrating an embodiment of an electrical assembly according to teachings of the present disclosure.

FIG. 4A is a schematic view of an embodiment of an electronic control unit (ECU) having a first configuration according to teachings of the present disclosure.

FIG. 4B is a schematic view of an embodiment of an electronic control unit (ECU) having a second configuration according to teachings of the present disclosure.

FIG. 5 is a schematic view generally illustrating an embodiment of an electrical assembly according to teachings of the present disclosure.

FIG. 6 is a schematic view generally illustrating an embodiment of an electrical assembly according to teachings of the present disclosure.

FIG. 7 is a schematic view generally illustrating an embodiment of an electrical assembly according to teachings of the present disclosure.

FIG. 8 is a schematic view generally illustrating an embodiment of an electrical assembly according to teachings of the present disclosure.

FIG. 9 is a flow diagram view generally illustrating an embodiment of a method of operating an electrical assembly according to teachings of the present disclosure.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

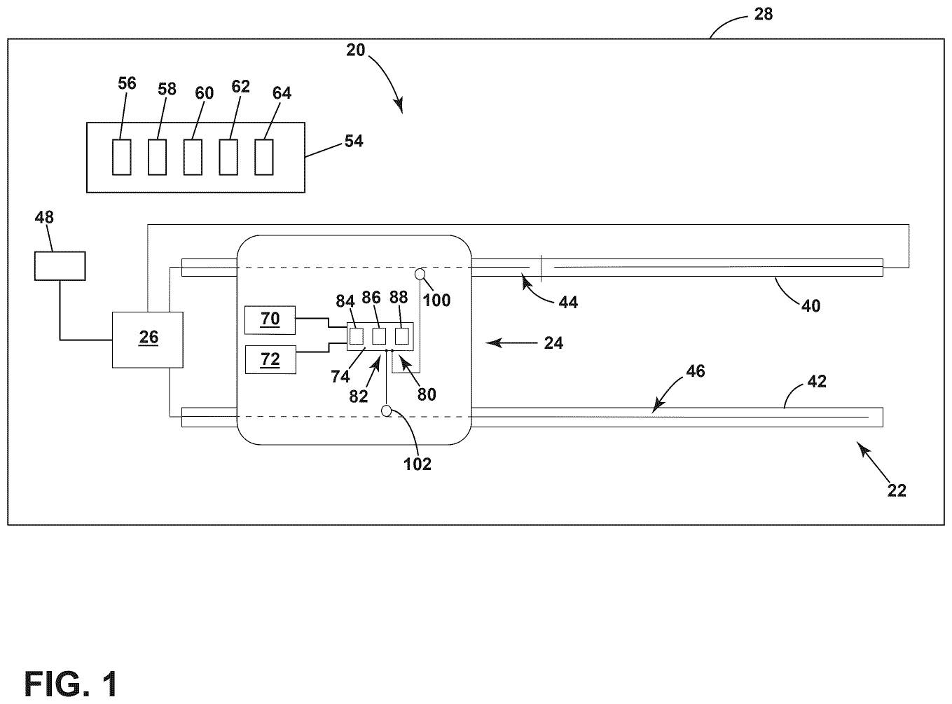

Referring to FIG. 1, an electrical assembly 20 is illustrated with a track assembly 22, a support assembly 24, and an electronic control unit (ECU) 26. The track assembly 22 includes a first track 40, a second track 42, a first conductor 44, and a second conductor 46. The first conductor 44 is connected to and/or disposed at least partially in the first track 40. The second conductor 46 is connected to and/or disposed at least partially in the second track 42. The ECU 26 is electrically connected to the first conductor 44, the second conductor 46, and a power source 48. The power source 48 can, for example, include a battery, such as a vehicle battery for vehicle applications.

The support assembly 24 is connectable to (e.g., mechanically and electrically), movable along and relative to, and/or removable from the track assembly 22. Optionally, the support assembly 24 is configured as a vehicle component, such as a seat or a console, among other configurations. The support assembly 24 includes a first sensor 70, a second sensor 72, and a sensor enabler 74 that move with the support assembly 24. The sensor enabler 74 includes a first terminal 80, a second terminal 82, a set of diodes 84, a set of comparators 86, and/or a set of switches 88. The sensor enabler 74 is electrically connected to the first sensor 70 and the second sensor 72. The sensor enabler 74 selectively electrically connects the first sensor 70 or the second sensor 72 to the first terminal 80 and the second terminal 82, such as according to an output from the ECU 26. For example, the set of diodes 84, the set of comparators 86, and/or the set of switches 88 can be electrically connected between the first and second sensors 70, 72 and the first and second terminals 80, 82.

The electrical assembly 20 can include a safety system 54 that can be in communication with and/or at least partially controlled by the ECU 26. The safety system 54 can include one or more of an airbag 56, a seat belt 58, a seat belt pretensioner 60, a display 62, or a speaker 64, among others. With some implementations, the electrical assembly 20 can be included with a vehicle 28.

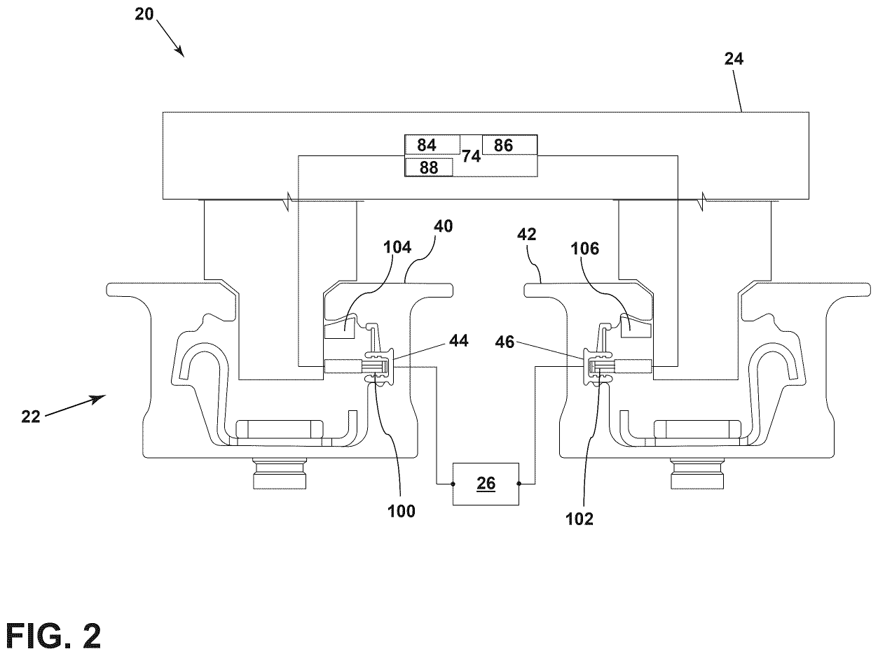

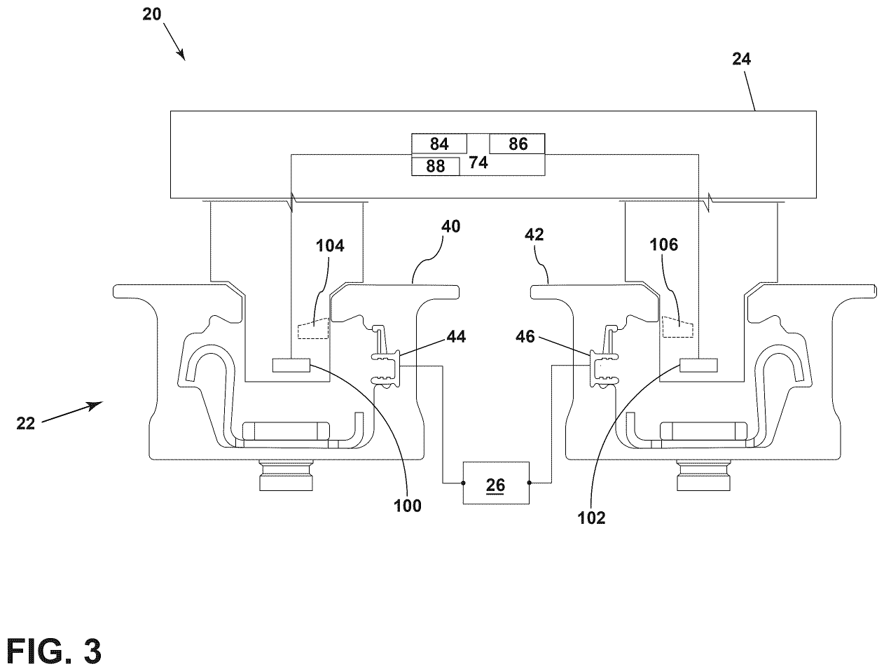

Referring to FIGS. 2 and 3, the support assembly 24 includes a first contact 100, a second contact 102, a first anchor 104, and a second anchor 106. The first and second contacts 100, 102 are movable (e.g., rotatable, translatable, etc.) between extended positions shown in FIG. 2 in which the first and second contacts 100, 102 are in contact and electrically connected with the first and second conductors 44, 46, respectively, and retracted positions shown in FIG. 3, in which the first and second contacts 100, 102 are not in contact with the first and second conductors 44, 46. In the retracted position, the first and second contacts 100, 102 can be disposed such that they do not restrict vertical removal of the support assembly 24 from the track assembly 22. The anchors 104, 106 are movable between extended positions shown in FIG. 2 in which the anchors 104, 106 are engaged with the first and second tracks 40, 42, respectively, and retracted positions shown in FIG. 3, in which the anchors 104, 106 are not engaged with the first and second tracks 40, 42. In the retracted position, the anchors 104, 106 can be disposed such that they do not restrict vertical removal of the support assembly 24 from the track assembly 22.

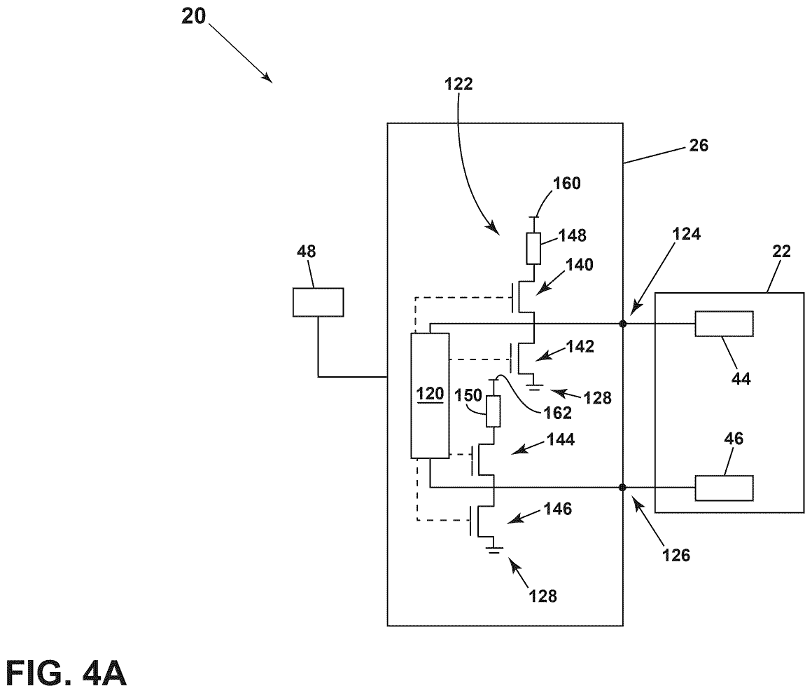

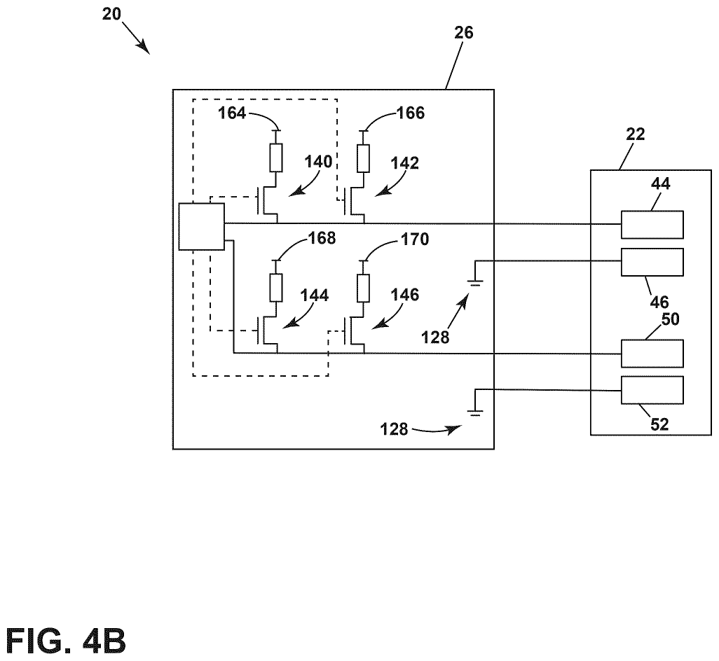

Referring to FIG. 4A, in a first configuration, the ECU 26 includes a controller 120, a plurality of switches 122 (e.g., “ECU switches”), a first ECU terminal 124, and a second ECU terminal 126. The plurality of switches 122, optionally, includes one or more of transistors, field effect transistors (FETs), metal oxide field effect transistors (MOSFETs), relays, or contactors, among others. The plurality of switches 122 includes a first switch 140, a second switch 142, a third switch 144, and a fourth switch 146. The first switch 140 and the third switch 144 are electrically connected to first and second voltage sources 160, 162, respectively, which can be connected to or included with the power source 48. The first switch 140 is electrically connected to the second switch 142 and the first ECU terminal 124. The third switch 144 is electrically connected to the fourth switch 146 and the second ECU terminal 126. The second switch 142 and the fourth switch 146 are electrically connected to the first ECU terminal 124 and the second ECU terminal 126, respectively, and connected to ground 128.

The controller 120 can operate the plurality of switches 122 to selectively connect the first voltage source with the first ECU terminal 124 and connect the second ECU terminal 126 to ground 128, or connect the first ECU terminal 124 to ground 128 and connect the second ECU terminal 126 to the second voltage source 162. For example, the controller 120 can operate the first switch 140 to a closed configuration and operate the second switch 142 to an open configuration to connect the first ECU terminal 124 to the first voltage source 160. The controller 120 can operate the third switch 144 to an open configuration and operate the fourth switch 146 to a closed configuration to connect the second ECU terminal 126 to ground 128. Additionally or alternatively, the controller 120 can operate the first switch 140 to an open configuration and operate the second switch 142 to a closed configuration to connect the first ECU terminal 124 to ground 128. The controller 120 can operate the third switch 144 to a closed configuration and operate the fourth switch 146 to a closed configuration to connect the second ECU terminal 126 to the second voltage source 162. In some implementations, resistors 148, 150 (e.g., pull-up resistors) can be connected between the first and second voltage sources 160, 162 and the first and third switches 140, 144, respectively.

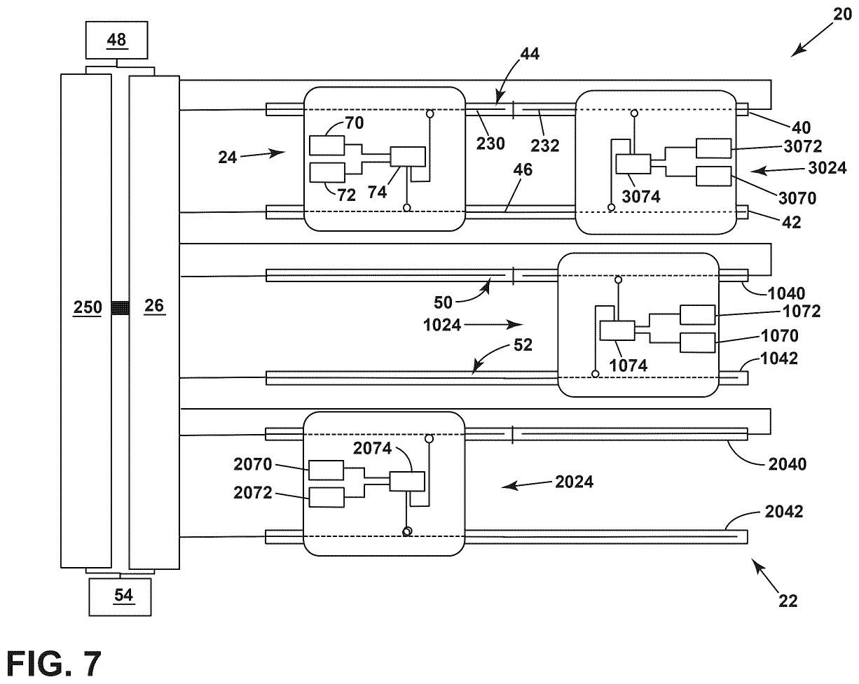

Referring to FIG. 4B, another configuration of the ECU 26 is illustrated. The first switch 140 is connected to and selectively electrically connects a third voltage source 164 and the first conductor 44. The second switch 142 is connected to and selectively electrically connects a fourth voltage source 166 and the first conductor 44. The third switch 144 is connected to and selectively electrically connects a fifth voltage source 168 and a third conductor 50 of the track assembly 22. The fourth switch 146 is connected to and selectively electrically connects a sixth voltage source 170 and the third conductor 50. The voltage sources 164-170 can each provide a different voltage. The ECU 26 can close the first and second switches 140, 142 to provide respective first and second voltages to the first conductor 44. The second conductor 46 can be connected to ground 128. The ECU 26 can close the third and fourth switches 144, 146 to provide respective third and fourth voltages to the third conductor 50. A fourth conductor 52 of the track assembly 22 can be connected to ground 128. The third and fourth conductors 50, 52 can be disposed in the first track 40, the second track 42, a combination of the first and second track 40, 42, or in other tracks of the track assembly 22 (see, e.g., tracks 1040, 1042, 2040, 2042 of FIG. 7).

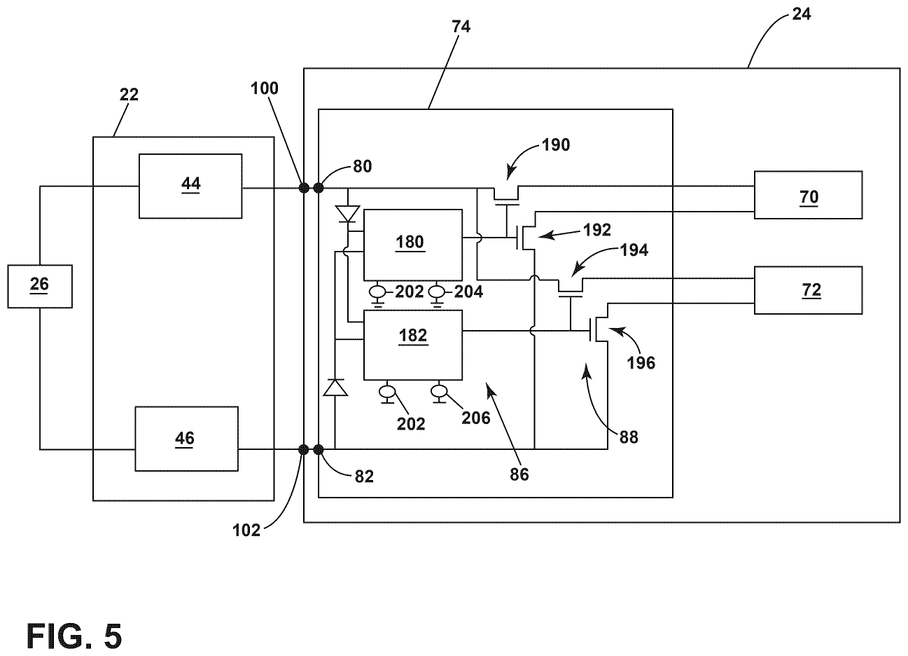

Referring to FIG. 5, the sensor enabler 74 of the support assembly 24 includes the set of comparators 86, which includes a first comparator 180 and a second comparator 182, a first switch 190, a second switch 192, a third switch 194, and a fourth switch 196. The first comparator 180 and the second comparator 182 are connected to the first terminal 80 and the second terminal 82. The first comparator 180 is connected to control the first switch 190 and the second switch 192. The second comparator 182 is connected to controller the third switch 194 and the fourth switch 196. The first switch 190 is connected between and selectively electrically connects the first terminal 80 with the first sensor 70. The second switch 192 is connected between and selectively electrically connects second terminal 82 with the first sensor 70. The third switch 194 is connected between and selectively electrically connects the first terminal 80 and the second sensor 72. The fourth switch 196 is connected between and selectively electrically connects the second terminal 82 with the second sensor 72. Optionally, the first and second comparators 180, 182 include window comparators and include low reference inputs 200, 202 and high reference inputs 204, 206 that define respective first and second windows of the first and second comparators 180, 182. The first and second windows can be different and nonoverlapping. The first and second comparators 180, 182 can operate to selectively electrically connect the first sensor 70 or the second sensor 72 with the first and second terminals 80, 82. For example, if a voltage across the first and second terminals 80, 82 is within the first window of the first comparator 180, the first comparator 180 provides an output to close the first and second switches 190, 192, which connects the first sensor 70 to the first and second terminals 80, 82 and the first and second contacts 100, 102. If the voltage across the first and second terminals 80, 82 is within the second window of the second comparator 182, the second comparator 182 provides an output to close the third and fourth switches 194, 196, which connects the second sensor 72 to the first and second terminals 80, 82. With some configurations, the ECU 26 can control the voltage across the first and second terminals 80, 82 to selectively connect to the first sensor 70 or the second sensor 72. For example, the ECU 26 can include the configuration shown in FIG. 4B. Additionally or alternatively, the first and second sensors 70, 72 may have a variable resistance/impedance that corresponds to a respective sensed value or parameter, and the ECU 26 and may utilize the resistance/impedance of the sensor 70, 72 (e.g., the voltage drop across the sensor 70, 72) to obtain the sensed value or parameter from the sensor 70, 72.

In accordance with the ECU 26 providing a first voltage outside of the first window and outside the second window (e.g., a zero voltage, between the reference voltages 204 and 202, or above the reference voltage 206), neither of the first sensor 70 and the second sensor 72 is electrically connected to the first and second terminals 80, 82. In accordance with the ECU 26 providing a second voltage within the first window (e.g., from the third voltage source 164 in FIG. 4B), the first comparator 180 closes the first switch 190 and the second switch 192 to connect the first sensor 70 to the first and second terminals 80, 82, such as to connect the ECU 26 with the first sensor 70 via the first and second conductors 44, 46. With the ECU 26 providing the second voltage, which is outside the second window, the second comparator 182 does not close the third and fourth switches 194, 196, leaving the second sensor 72 disconnected from the first and second terminals 80, 82. In accordance with the ECU 26 providing a third voltage within the second window (e.g., from the fourth voltage source 166 in FIG. 4B), the second comparator 182 closes the third switch 194 and the fourth switch 196 to connect the second sensor 72 to the first and second terminals 80, 82. With the ECU 26 providing the third voltage, which is outside the first window, the first comparator 180 does not close the first and second switches 190, 192, leaving the first sensor 70 disconnected from the first and second terminals 80, 82. The ECU 26 can provide the second voltage to obtain information from the first sensor 70, and can provide the third voltage to obtain information from the second sensor 72.

The sensor enabler 74 can include a set of switches 88 (e.g., switches 190-196) and a set of comparators 86 (e.g., comparators 180, 182) connected to the set of switches 88. The support assembly 24 can include a set of sensors (e.g., first and second sensors 70, 72). The set of comparators 86 are connected to (i) the first terminal 80, (ii) the second terminal 82, (iii) a respective pair of switches of the set of switches 88. Each respective pair of switches can be connected to (i) the first terminal 80, (ii) the second terminal 82, and (iii) a respective sensor of the set of sensors. The comparators of the set of comparators 86 can each include a different window that does not overlap with other windows.

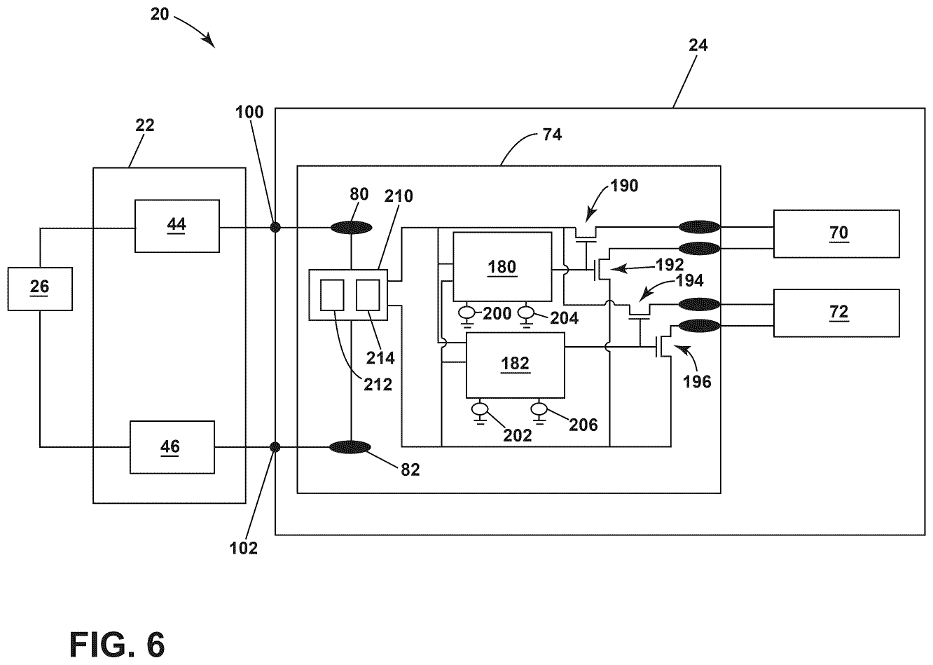

Referring to FIG. 6, the support assembly 24 can include a polarity adapter 210 having at least one of a polarity adapter switch 212 or a polarity adapter diode 214. The polarity adapter 210 is between (i) the first and second contacts 100, 102 and (ii) the switches 140-146, the first comparator 180, and the second comparator 182. The support assembly 24 can be connected to the track assembly 22 in a first configuration (FIG. 1) or a second configuration (e.g., a reverse configuration). In the first configuration, the first contact 100 may be in contact with the first conductor 44 and the second contact 102 may be in contact with the second conductor 46. In the second configuration, the first contact 100 may be in contact with the second conductor 46 and the second contact 102 may be in contact with the first conductor 44. The polarity adapter 210 can be configured to connect the first and third switches 140, 144 to the first conductor 44 and connect the second and fourth switches 142, 146 to the second conductor 46 when the support assembly 24 is connected to the track assembly 22 in the first configuration or the second configuration (e.g., regardless of which the first and second conductors 44, 46 the first and second contacts 100, 102 are in contact with. Examples of polarity adapters are described in U.S. Pat. No. 11,807,142, which is hereby incorporated by reference in its entirety as though fully set forth herein.

Referring to FIG. 7, the electrical assembly 20 is illustrated with a plurality of support assemblies, including the support assembly 24, a second support assembly 1024, a third support assembly 2024, and/or a fourth support assembly 3024. Additionally or alternatively, the track assembly 22 can include a plurality of pairs of tracks, including the first and second tracks 40, 42, a third track 1040 and a fourth track 1042, and a fifth track 2040 and a sixth track 2042. The support assemblies 24, 1024, 2024 can be connected to any of the pairs of tracks 40, 42, 1040, 1042, 2040, 2042. For example, the support assembly 24 and the fourth support assembly 3024 can be connected to the first and second tracks 40, 42, the second support assembly 1024 can be connected to the third and fourth tracks 1040, 1042, and the third support assembly 2024 can be connected to the fifth and sixth tracks 2040, 2042. The support assembly 24 is shown connected to the first and second tracks 40, 42 in the first configuration and the fourth support assembly 3024 is shown connected to the first and second tracks 40, 42 in the second configuration. The support assemblies 1024, 2024, 3024 can include configurations that are similar to the support assembly 24, such as with respective sensors 1070, 1072, 2070, 2072, 3070, 3072, and sensor enablers 2074, 2074, 3074. The sensors 70, 72, 1070, 1072, 2070, 2072, 3070, 3072 can, for example, each provide a different resistance/impedance value or range of values, which can allow the ECU 26 to identify the respective support assembly 24, 1024, 2024, 3024.

Optionally, a conductor of a track, such as the first conductor 44 of the first track 40 can include a plurality of separate portions, such as a first conductor first portion 230 and a first conductor second portion 232. The first conductor first portion 230 can extend along a first portion of the first track 40 (e.g., a forward portion) and the first conductor second portion 232 can extend along a second portion of the first track 40 (e.g., a rear portion). The ECU 26 can be separately connected to the portions 230, 232. The conductor portions 230, 232 may extend along and/or define respective zones of the pair of tracks 40, 42. A support assembly 24, 1024, 2024, 3024 can be connectable to each zone.

The electrical assembly 20 optionally includes a zone controller 250 electrically connected to the ECU 26 and/or the power source 48. In some implementations, the zone controller 250 is incorporated with the ECU 26, or vice versa. The zone controller 250 can be utilized for zonal architectures, such as instead of or in addition to a domain-based architecture.

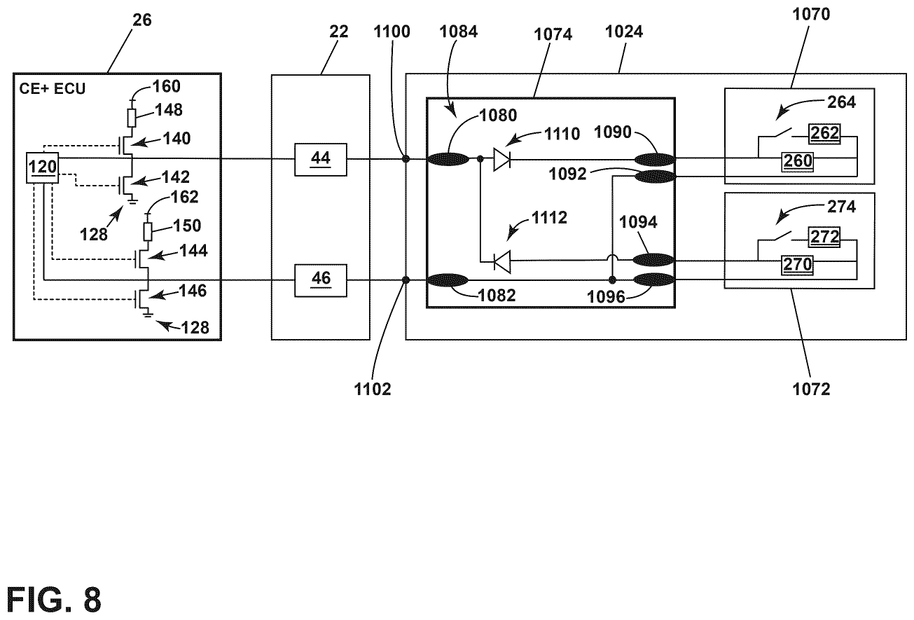

Referring to FIG. 8, another sensor enabler 1074, included with the support assembly 1024 and connected to first and second sensors 1070, 1072, is illustrated. The sensor enabler 1074 includes a set of diodes 1084, a first terminal 1080, a second terminal 1082, a third terminal 1090, a fourth terminal 1092, a fifth terminal 1094, and a sixth terminal 1096. When the support assembly 1024 is connected in the first configuration, the first terminal 1080 is connected to a first electrical contact 1100 of the support assembly 1024, and the second terminal 1082 is connected to a second electrical contact 1102 of the support assembly 1024. The third and fourth terminals 1090, 1092 are connected to the first sensor 1070. The fifth and sixth terminals 1094, 1096 are connected to the second sensor 72. The second terminal 1082 is connected to the fourth terminal 1092 and the sixth terminal 1096. The sensor enabler 1074 may be utilized with the ECU 26 having the configuration shown in FIG. 4A.

The set of diodes 1084 includes a first diode 1110 and a second diode 1112. The first diode 1110 is connected to the first terminal 1080 and the third terminal 1090 to allow current to flow from the first terminal 1080 to the third terminal 1090 and to block current flow from the third terminal 1090 to the first terminal 1080. The second diode 1102 is connected to the first terminal 1080 and the fifth terminal 1094 to allow current to flow from the fifth terminal 1094 to the first terminal 1080 and to block current flow from the first terminal 1080 to the fifth terminal 1094. When the ECU 26 provides a positive voltage to the first terminal 1080 and connects the second terminal 1082 to ground 128 (e.g., by closing the first and fourth switches 140, 146), current flows through the first diode 1110 to the third terminal 1090, from the third terminal 1090 through the first sensor 1070 to the fourth terminal 1092, and from the fourth terminal 1092 to the second terminal 1082. The ECU 26 may then sense a resistance, impedance, and/or voltage drop across the first and second terminals 1080, 1082 to obtain information from the first sensor 1070. When the ECU 26 provides a positive voltage to the second terminal 1082 and connects the first terminal 1080 to ground 128 (e.g., by closing the second and third switches 142, 144), current flows through the sixth terminal 1096 to the second sensor 1072, through the second sensor 1072 to the fifth terminal 1094, and from the fifth terminal 1094 through the second diode 1112 to the first terminal 1080. The ECU 26 may then sense a resistance, impedance, and/or voltage drop across the first and second terminals 1080, 1082 to obtain information from the second sensor 1072.

The first sensor 1070 is illustrated with a first resistor 260, a second resistor 262, and a first sensor switch 264 in parallel with the first resistor 260. The first resistor 260 is connected to (e.g., across) the third and fourth terminals 1090, 1092. The second resistor 262 and the first sensor switch 264 are connected in series with each other in and parallel with the first resistor 260 (e.g., across the third and fourth terminals 1090, 1092). When the first sensor switch 264 is open, the resistance and impedance of the first sensor 1070 correspond to the first resistor 260 only. When the first sensor switch 264 is closed, the resistance and impedance of the first sensor 1070 correspond to the first and second resistors 260, 262 connected in parallel. The first and second resistors 260, 262 may or may not have the same resistance/impedance.

The second sensor 1072 is configured in a similar manner as the first sensor 1070. For example, the second sensor 1072 can include a third resistor 270, a fourth resistor 272, and a second sensor switch 274. The third resistor 270 is connected to (e.g., across) the fifth and sixth terminals 1094, 1096. The fourth resistor 272 and the second sensor switch 274 are connected in series with each other in and parallel with the third resistor 270 (e.g., across the fifth and sixth terminals 1094, 1096). When the second sensor switch 274 is open, the resistance and impedance of the second sensor 1072 correspond to the third resistor 270 only. When the second sensor switch 274 is closed, the resistance and impedance of the second sensor 1072 correspond to the third and fourth resistors 270, 272 connected in parallel. The third and fourth resistors 270, 272 may or may not have the same resistance/impedance. The first and second resistors 260, 262 can have different resistance/impedance than the third and fourth resistors 270, 272 in series and parallel.

The sensors 70, 72, 1070, 1072, 2070, 2072, 3070, 3072 can, with some implementations, include a seat belt sensor and an occupancy sensor, respectively. For example, a buckled seat belt 58 can close the first sensor switch 264 and an occupant seated on the support assembly 24 can close the second sensor switch 274. The ECU 26 may provide the positive voltage to the first terminal 1080 to obtain seat belt information (e.g., engaged or disengaged) from the first sensor 1070. For example, if the first sensor 1070 has a resistance/impedance corresponding to only the first resistor 260, the ECU 26 can determine that a seat belt 58 is disengaged/unbuckled. If the first sensor 1070 has a resistance/impedance corresponding to the first and second resistors 260, 262 in parallel, the ECU 26 can determine that the seat belt 58 is engaged/buckled. The ECU 26 may provide the positive voltage to the second terminal 1082 to obtain occupancy information (e.g., occupied or not) from the second sensor 1072. For example, if the second sensor 1072 has a resistance/impedance corresponding to only the third resistor 270, the ECU 26 can determine that the support assembly 1024 is unoccupied. If the second sensor 1072 has a resistance/impedance corresponding to the third and fourth resistors 270, 272 in parallel, the ECU 26 can determine that the support assembly 24 is occupied.

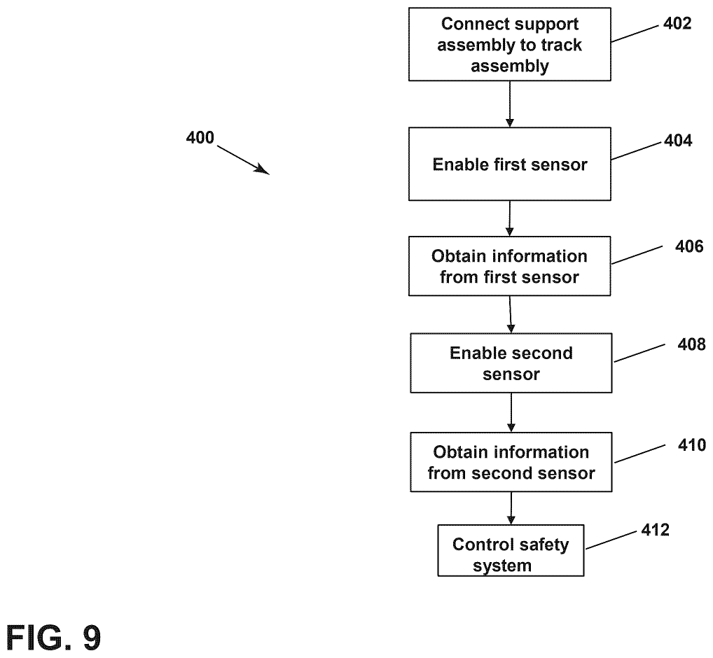

Referring to FIG. 9, a method 400 of operating the electrical assembly 20 is illustrated. The method 400 includes connecting a support assembly (e.g., support assembly 24) to the track assembly 22 (block 402), which can include electrically connecting the electrical contacts 100, 102 to the first and second conductors 44, 46 and/or mechanically connecting the anchors 104, 106 to the first and second tracks 40, 42. The method 400 includes the ECU 26 operating the sensor enabler 74 to enable one of the first sensor 70 or the second sensor 72 (block 404) and obtaining information from the enabled sensor (block 406). The method 400 includes the ECU 26 operating the sensor enabler 74 to enable the other of the first sensor 70 or the second sensor 72 (block 408) and obtaining information from the enabled sensor (block 410). The method 400 can include controlling the safety system 54 according to the information from the first and second sensors 70, 72 (block 412). Controlling the safety system 54 can, for example, include actuating the seat belt pretensioner 60 if the first sensor 70 indicates the seat belt 58 is buckled and/or include deploying the airbag 56 if the second sensor 72 indicates that the support assembly 24 is occupied, and the ECU 26 determines or receives information that a crash is imminent or has occurred. Additionally or alternatively, controlling the safety system 54 can include providing an alert, such as a visual alert, an audible alert, or both. For example, if the first and second sensors 70, 72 indicate that the support assembly 24 is occupied but the seat belt 58 is unbuckled, the safety system 54 can provide a visual and audible seat belt reminder alert via the display 62 and the speaker 64. While the method 400 is described in connection with the support assembly 24, some or all portions of the method 400 can, additionally or alternatively, be carried out with one or more of the support assemblies 1024, 2024, 3024.

With some examples, the support assembly 24 can include more than two sensors 70, 72. The sensor enabler 74 can be scaled for the additional sensors. For example, the sensor enabler 74 can include additional diodes, switches, and/or comparators.

In some examples, the sensor enabler 74 may utilize the switches 190-196, independent of a comparator, to selectively electrically connect the sensors 70, 72 to the first contact 100 and the second contact 102. For example, a turn-on parameter (e.g., voltage) of the switches 190, 192 can be different than the turn-on parameter of the switches 194, 196, and the ECU 26 can provide control signals corresponding to the different turn-on parameters. With such a configuration, control inputs of the switches 190-196 may be connected to the contacts 100, 102.

Embodiments of electrical assemblies 20 can facilitate communication with between the ECU 26 and the support assembly 24, such as between the first and second sensors 70, 72 and the ECU 26 via the first and second conductors 44, 46. Communication with two or more sensors via the same conductors can allow for fewer conductors (e.g., instead of two conductors for each sensor), which may be desirable where the total number of conductors that can be added to a track is limited because of size/space and weight constraints (e.g., where adding a conductor for each sensor may not be feasible). Additionally or alternatively, the sensor enabler 74, 1074 can be a passive component (e.g., without a processor, controller, encoder/decoder, etc.), which can reduce power consumption and assembly complexity. Embodiments of electrical assemblies 20 can be easily scalable, such as for additional support assemblies, without significant changes.

While various examples are described in connection with an ECU 26 provide different voltage levels to a sensor enabled to enable certain sensors, the ECU can, additionally or alternatively, provide other versions of excitation/enabling signals, such as via different current levels and/or signals with different frequencies, to enables certain sensors.

The instant disclosure includes the following non-limiting embodiments:

An electrical assembly, comprising: an electronic control unit (ECU); a track assembly electrically connected to the ECU, the track assembly including a first conductor and a second conductor; and a support assembly configured for connection with and movement along the track assembly relative to the ECU, the support assembly including: a first sensor, a second sensor, and a sensor enabler electrically connected to the first sensor and the second sensor, the sensor enabler including a first terminal, a second terminal, and at least one of a diode, a comparator, or a switch; wherein the sensor enabler selectively electrically connects the first sensor or the second sensor with the first terminal and the second terminal according to an output from the ECU.

The electrical assembly of any preceding embodiment, wherein the sensor enabler includes the comparator and a second comparator.

The electrical assembly of any preceding embodiment, wherein the sensor enabler includes: a first switch connected between the first terminal and the first sensor, and a second switch connected between second terminal and the first sensor.

The electrical assembly of any preceding embodiment, wherein an output of the comparator is connected to the first switch and the second switch.

The electrical assembly of any preceding embodiment, wherein the sensor enabler includes: a third switch connected between the first terminal and the second sensor; and a fourth switch connected between the second terminal and the second sensor.

The electrical assembly of any preceding embodiment, wherein an output of the second comparator is connected to the third switch and the fourth switch.

The electrical assembly of any preceding embodiment, wherein the comparator includes a first window comparator having a first window, and the second comparator includes a second window comparator having a second window that is different than the first window.

The electrical assembly of any preceding embodiment, wherein the support assembly includes a first electrical contact, a second electrical contact, and a polarity adapter connected between (i) the first and second electrical contacts, and (ii) the first, second, third, and fourth switches, the comparator, and the second comparator; and the polarity adapter includes at least one of a polarity adapter switch or a polarity adapter diode.

The electrical assembly of any preceding embodiment, wherein the comparator and the second comparator are configured such that: in accordance with the ECU providing a first voltage outside of the first window and the second window, neither of the first sensor and the second sensor is electrically connected to the first and second terminals; in accordance with the ECU providing a second voltage within the first window, the comparator closes the first switch and the second switch to connect the first sensor to the first and second terminals; and in accordance with the ECU providing a third voltage within the second window, the second comparator closes the third switch and the fourth switch to connect the second sensor to the first and second terminals.

The electrical assembly of any preceding embodiment, wherein, in a connected configuration of the support assembly with the track assembly, the first terminal is electrically connected with the first conductor and the second terminal is electrically connected with the second conductor.

The electrical assembly of any preceding embodiment, wherein the ECU is configured to provide the second voltage to obtain information from the first sensor and provide the third voltage to obtain information from the second sensor.

The electrical assembly of any preceding embodiment, wherein the sensor enabler includes the diode and a second diode; the diode is connected between the first terminal and the first sensor; and the second diode is connected between the first terminal and the second sensor.

The electrical assembly of any preceding embodiment, wherein the diode permits current flow in a first direction from the first terminal to the first sensor; and wherein the second diode permits current flow in a second direction from the second sensor to the first terminal.

The electrical assembly of any preceding embodiment, wherein the first sensor includes a first resistor connected in parallel with a second resistor and a first sensor switch.

The electrical assembly of any preceding embodiment, wherein the second sensor includes a third resistor connected in parallel with a fourth resistor and a second sensor switch.

The electrical assembly of any preceding embodiment, wherein the ECU is configured to provide current in the first direction to the first conductor to obtain information from the first sensor and provide current in the second direction to the second conductor to obtain information from the second sensor.

The electrical assembly of any preceding embodiment, wherein the sensor enabler includes a set of switches and a set of comparators connected to the set of switches, the set of comparators including the comparator; and the support assembly includes a set of sensors including the first sensor and the second sensor.

The electrical assembly of any preceding embodiment, wherein comparators of the set of comparators are connected to (i) the first terminal, (ii) the second terminal, (iii) a respective pair of switches of the set of switches.

The electrical assembly of any preceding embodiment, wherein each respective pair of switches is connected to (i) the first terminal, (ii) the second terminal, and (iii) a respective sensor of the set of sensors.

The electrical assembly of any preceding embodiment, wherein the comparators of the set of comparators each includes a different window that does not overlap with other windows.

The electrical assembly of any preceding embodiment, wherein the support assembly includes a seat or a console.

A vehicle including the electrical assembly of any preceding embodiment.

A seat assembly comprising the electrical assembly of any preceding embodiment.

A method of operating the electrical assembly of any preceding embodiment, the method comprising: connecting the support member to the track assembly; enabling the first sensor; obtaining information from the first sensor; enabling the second sensor; obtaining information from the second sensor; and controlling the safety system according to the information from the first sensor and/or the information from the second sensor.

An electronic controller configured to implement the method of any preceding embodiment.

A vehicle comprising the electronic controller of any preceding embodiment.

A non-transitory computer-readable storage medium having a computer program encoded thereon for implementing the method of any preceding embodiment.

A vehicle comprising the non-transitory computer-readable storage medium of any preceding embodiment.

In examples, a controller or ECU (e.g., the ECU 26) may include an electronic controller and/or include an electronic processor, such as a programmable microprocessor and/or microcontroller. In embodiments, a controller may include, for example, an application specific integrated circuit (ASIC) and/or an embedded controller. A controller may include a central processing unit (CPU), a memory (e.g., a non-transitory computer-readable storage medium), and/or an input/output (I/O) interface. A controller may be configured to perform various functions, including those described in greater detail herein, with appropriate programming instructions and/or code embodied in software, hardware, and/or other medium. In embodiments, a controller may include a plurality of controllers. In embodiments, a controller may be connected to a display, such as a touchscreen display.

Various examples/embodiments are described herein for various apparatuses, systems, and/or methods. Numerous specific details are set forth to provide a thorough understanding of the overall structure, function, manufacture, and use of the examples/embodiments as described in the specification and illustrated in the accompanying drawings. It will be understood by those skilled in the art, however, that the examples/embodiments may be practiced without such specific details. In other instances, well-known operations, components, and elements have not been described in detail so as not to obscure the examples/embodiments described in the specification. Those of ordinary skill in the art will understand that the examples/embodiments described and illustrated herein are non-limiting examples, and thus it can be appreciated that the specific structural and functional details disclosed herein may be representative and do not necessarily limit the scope of the embodiments.

Reference throughout the specification to “examples, “in examples,” “with examples,” “in the illustrated example,” “various embodiments,” “with embodiments,” “in embodiments,” “an embodiment,” “with some configurations,” “in some configurations,” or the like, means that a particular feature, structure, or characteristic described in connection with the example/embodiment is included in at least one embodiment. Thus, appearances of the phrases “examples, “in examples,” “with examples,” “in the illustrated example,” “in various embodiments,” “with embodiments,” “in embodiments,” “an embodiment,” “with some configurations,” “in some configurations,” or the like, in places throughout the specification are not necessarily all referring to the same embodiment. Furthermore, the particular features, structures, and/or characteristics may be combined in any suitable manner in one or more examples/embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof. The word “exemplary” is used herein to mean “serving as a non-limiting example.”

It should be understood that references to a single element are not necessarily so limited and may include one or more of such element, unless the context clearly indicates otherwise. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of examples/embodiments.

“One or more” includes a function being performed by one element, a function being performed by more than one element, e.g., in a distributed fashion, several functions being performed by one element, several functions being performed by several elements, or any combination of the above. The term “at least one of” in the context of, e.g., “at least one of A, B, and C” or “at least one of A, B, or C” includes only A, only B, only C, or any combination or subset of A, B, and C, including any combination or subset of one or a plurality of A, one or a plurality of B, and one or a plurality of C. A “set” of elements can include any number of one or more elements.

Although the terms first, second, etc. are, in some instances, used herein to describe various elements, these elements should not be limited by these terms. These terms are only used to distinguish one element from another. For example, a first element could be termed a second element, and, similarly, a second element could be termed a first element, without departing from the scope of the various described embodiments. The first element and the second element are both elements, but they are not the same element.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. The term “and/or” as used herein refers to and encompasses any and all possible combinations of one or more of the associated listed items. Uses of “and” and “or” are to be construed broadly (e.g., to be treated as “and/or”). For example and without limitation, uses of “and” do not necessarily require all elements or features listed, and uses of “or” are inclusive unless such a construction would be illogical. The terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

Joinder references (e.g., attached, coupled, connected, and the like) are to be construed broadly and may include intermediate members between a connection of elements, relative movement between elements, direct connections, indirect connections, fixed connections, movable connections, operative connections, indirect contact, and/or direct contact. As such, joinder references do not necessarily imply that two elements are directly connected/coupled and in fixed relation to each other. Connections of electrical components, if any, may include mechanical connections, electrical connections, wired connections, and/or wireless connections, among others. Uses of “e.g.” and “such as” in the specification are to be construed broadly and are used to provide non-limiting examples of embodiments of the disclosure, and the disclosure is not limited to such examples.

While processes, systems, and methods may be described herein in connection with one or more steps in a particular sequence, such methods may be practiced with the steps in a different order, with certain steps performed simultaneously, with additional steps, and/or with certain described steps omitted.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

References to a vehicle can include one or more of a variety of vehicles, including, without limitation, a passenger car (e.g., a sedan, a pickup truck, a sport utility vehicle, a crossover, etc.), a truck, a bus, a recreational vehicle, a plane, or a boat, among others.

All matter contained in the above description or shown in the accompanying drawings shall be interpreted as illustrative only and not limiting. Changes in detail or structure may be made without departing from the present disclosure.

A controller, an electronic control unit (ECU), a system, and/or a processor as described herein may include a conventional processing apparatus known in the art, which may be capable of executing preprogrammed instructions stored in an associated memory, all performing in accordance with the functionality described herein. To the extent that the methods described herein are embodied in software, the resulting software can be stored in an associated memory and can also constitute means for performing such methods. Such a system or processor may further be of the type having ROM, RAM, RAM and ROM, and/or a combination of non-volatile and volatile memory so that any software may be stored and yet allow storage and processing of dynamically produced data and/or signals.

An article of manufacture in accordance with this disclosure may include a non-transitory computer-readable storage medium having a computer program encoded thereon for implementing logic and other functionality described herein. The computer program may include code to perform one or more of the methods disclosed herein. Such embodiments may be configured to execute via one or more processors, such as multiple processors that are integrated into a single system or are distributed over and connected together through a communications network, and the communications network may be wired and/or wireless. Code for implementing one or more of the features described in connection with one or more embodiments may, when executed by a processor, cause a plurality of transistors to change from a first state to a second state. A specific pattern of change (e.g., which transistors change state and which transistors do not), may be dictated, at least partially, by the logic and/or code.

What is claimed is:

1. An electrical assembly, comprising:
an electronic control unit (ECU);
a track assembly electrically connected to the ECU, the track assembly including a first conductor and a second conductor; and
a support assembly configured for connection with and movement along the track assembly relative to the ECU, the support assembly including:
a first sensor,
a second sensor, and
a sensor enabler electrically connected to the first sensor and the second sensor, the sensor enabler including a first terminal, a second terminal, and at least one of a diode, a comparator, or a switch;
wherein the sensor enabler selectively electrically connects the first sensor or the second sensor with the first terminal and the second terminal according to an output from the ECU.

2. The electrical assembly of claim 1, wherein the sensor enabler includes the comparator and a second comparator.

3. The electrical assembly of claim 2, wherein the sensor enabler includes:
a first switch connected between the first terminal and the first sensor, and
a second switch connected between second terminal and the first sensor.

4. The electrical assembly of claim 3, wherein an output of the comparator is connected to the first switch and the second switch.

5. The electrical assembly of claim 4, wherein the sensor enabler includes:
a third switch connected between the first terminal and the second sensor; and
a fourth switch connected between the second terminal and the second sensor.

6. The electrical assembly of claim 5, wherein an output of the second comparator is connected to the third switch and the fourth switch.

7. The electrical assembly of claim 6, wherein the comparator includes a first window comparator having a first window, and the second comparator includes a second window comparator having a second window that is different than the first window.

8. The electrical assembly of claim 7, wherein the support assembly includes a first electrical contact, a second electrical contact, and a polarity adapter connected between (i) the first and second electrical contacts, and (ii) the first, second, third, and fourth switches, the comparator, and the second comparator; and
the polarity adapter includes at least one of a polarity adapter switch or a polarity adapter diode.

9. The electrical assembly of claim 7, wherein the comparator and the second comparator are configured such that:
in accordance with the ECU providing a first voltage outside of the first window and the second window, neither of the first sensor and the second sensor is electrically connected to the first and second terminals;
in accordance with the ECU providing a second voltage within the first window, the comparator closes the first switch and the second switch to connect the first sensor to the first and second terminals; and
in accordance with the ECU providing a third voltage within the second window, the second comparator closes the third switch and the fourth switch to connect the second sensor to the first and second terminals.

10. The electrical assembly of claim 9, wherein, in a connected configuration of the support assembly with the track assembly, the first terminal is electrically connected with the first conductor and the second terminal is electrically connected with the second conductor.

11. The electrical assembly of claim 9, wherein the ECU is configured to provide the second voltage to obtain information from the first sensor and provide the third voltage to obtain information from the second sensor.

12. The electrical assembly of claim 1, wherein the sensor enabler includes the diode and a second diode;
the diode is connected between the first terminal and the first sensor; and
the second diode is connected between the first terminal and the second sensor.

13. The electrical assembly of claim 12, wherein the diode permits current flow in a first direction from the first terminal to the first sensor; and
wherein the second diode permits current flow in a second direction from the second sensor to the first terminal.

14. The electrical assembly of claim 13, wherein the first sensor includes a first resistor connected in parallel with a second resistor and a first sensor switch.

15. The electrical assembly of claim 14, wherein the second sensor includes a third resistor connected in parallel with a fourth resistor and a second sensor switch.

16. The electrical assembly of claim 15, wherein the ECU is configured to provide current in the first direction to the first conductor to obtain information from the first sensor and provide current in the second direction to the second conductor to obtain information from the second sensor.

17. The electrical assembly of claim 1, wherein the sensor enabler includes a set of switches and a set of comparators connected to the set of switches, the set of comparators including the comparator; and
the support assembly includes a set of sensors including the first sensor and the second sensor.

18. The electrical assembly of claim 17, wherein comparators of the set of comparators are connected to (i) the first terminal, (ii) the second terminal, (iii) a respective pair of switches of the set of switches.

19. The electrical assembly of claim 18, wherein each respective pair of switches is connected to (i) the first terminal, (ii) the second terminal, and (iii) a respective sensor of the set of sensors.

20. The electrical assembly of claim 19, wherein the comparators of the set of comparators each includes a different window that does not overlap with other windows.
